(19) United States
(12) Patent Application Publication
(10) Pub. No.: US 2017/0108770 A1
(43) Pub. Date: Apr. 20, 2017

(54) THIN-FILM MASK, FITTING AIDS, FITTING AND EXPOSURE DEVICE AND FITTING METHOD FOR THE THIN-FILM MASK PASTED ON A CURVED SUBSTRATE

(71) Applicants: Ming-An HSU, Hsinchu (TW); Wen-Fu LIN, Toufen Township (TW)

(72) Inventors: Ming-An HSU, Hsinchu (TW); Wen-Fu LIN, Toufen Township (TW)

(21) Appl. No.: 15/293,619

(22) Filed: Oct. 14, 2016

(30) Foreign Application Priority Data
Oct. 15, 2015 (TW) 104133885
Oct. 15, 2015 (TW) 104216525

(51) Int. Cl. G03F 1/42; G03F 1/60

(52) U.S. Cl. CPC G03F 1/42; G03F 1/60

(57) ABSTRACT

A thin-film mask, fitting aids, fitting and exposure assistant device and fitting method for the thin-film mask paste on a curved substrate is disclosed. The disclosure uses the fitting aids to apply pressure on the thin-film mask to paste on the curved substrate. After the template device had formed, send the template device to the exposure machine, and the high resolution color photoresist pattern is made on the curved substrate.

### FIELD OF THE INVENTION

The present disclosure relates to a mask, especially to a thin-film mask, fitting aids, fitting and exposure assistant device and fitting method for the thin-film mask pasted on a curved substrate.

### BACKGROUND

Nowadays, the smart device, such as smart phone, smart watch or smart medical devices, with large-screen monitor is common and makes user receiving messages easier than before. Moreover, not only the size and the function are important for the large-screen monitors, the visual appearance including the shape, the contour and the color is also a part which is paid attention to. A stellar exterior design and the manufacturing process thereof makes the large-screen monitor having individuation and attractive appearance in the same time. Among them, the large-screen monitor with curved shell is the most popular and attractive one which might lead the fashion and tread of future.

Currently used methods for manufacturing the curved shell and the pattern thereon of the smart device are described as follows: transfer printing and laser engraving after ink jet. Said transfer printing is preparing the pattern first and transferring the pattern to the target curved surface. Though the processing cost of transfer printing is low, however, the transfer printing technique has some drawback such as the slow processing speed, costly material, and the low resolution of printing. On the other side, as the name suggests, said laser engraving after ink jet is jetting the ink to the target curved surface first and then engraving the target curved surface to get the pattern by laser. This method costs high in material, equipment and processing and processes slow but with high printing resolution. The minimum resolution is up from 20 um.

Accordingly, how to provide a method to manufacture the curved shell and the pattern thereon with low processing and material cost, high processing speed and high printing resolution and a method to make colorful patterns on a curved and solid shell has become the major emphasis of the smart device firm. One technique is called photolithography which coats a photoresist layer on the curved shell and uses light to transfer a geometric pattern to the resist layer on the curved shell. However, how to etch the curved shell by photo mask is the major direction of the related field.

### SUMMARY

In order to achieve the above objective and other purposes, the present disclosure provide a thin-film mask, fitting aids, fitting and exposure device and fitting method for the thin-film mask pasted on a curved substrate. Applying a fitting aid to curve the thin-film mask and to make the thin-film mask pasting on the curved substrate, therefore, a curve surface pattern could be patterned on a curved substrate. By using the apparatus and method of present disclosure, the curved surface patterns on the curved substrate can be mass production by the light resist technique, and increase the quality, the precision and the yield of the products.

The present disclosure provides a thin-film mask for attaching to a curved substrate to form a photoresist layer on the curved substrate, and comprising: a thin-film substrate, composed of a flexible material; and a thin-film mask layer, formed on the thin-film substrate, having a visible pattern and used to attach to the photoresist layer of the curved substrate; wherein the thickness of the thin-film substrate is between 1 micrometer and 100 micrometers, the thickness of the thin-film mask layer is between 10 nanometers and 3000 nanometers.

The present disclosure also provides a fitting aid for which assists the thin-film mask to paste on the curved substrate when applying a pressure and acts as an interface between the thin-film mask and a exposure device, which comprising: a flexible sheet, composed of an elastic material with high transmittance, passed through by the light having a wavelength between 300 nanometers and 500 nanometers, deformed by an outer force to make the thin-film mask pasting closely on the photoresist layer of the curved substrate while the thin-film mask is attached to the curved substrate, and curved the thin-film mask.

The present disclosure provides a fitting and exposure assistant device for forming a photoresist layer with a curved surface pattern on a curved substrate, comprising: a thin-film mask which comprising a thin-film substrate, composed of a flexible material, disposing a plurality of positioning holes which is positioning and aligning the thin-film substrate to the curved substrate by a fitting aid, and a thin-film mask layer, formed on the thin-film substrate, having a visible pattern, wherein the thickness of the thin-film substrate is between 1 micrometer and 100 micrometers, the thickness of the thin-film mask layer is between 10 nanometers and 3000 nanometers; a flexible sheet, composed by a elastic material with high transmittance, passed through by the light having a wavelength between 300 nanometers and 500 nanometers, wherein the flexible sheet is deformed by an outer force to make the thin-film mask pasting on the photoresist layer of the curved substrate closely while the thin-film mask is attached to the curved substrate, and curves the surface of the thin-film mask; wherein the flexible sheet, the thin-film mask layer and the curved substrate are piled up in order, and exposed together in a exposure device to formed the curved pattern on the photoresist layer.

The present disclosure also provides a fitting and exposure assistant device for forming a photoresist layer with a curved surface pattern on a curved substrate, comprising: a thin-film mask comprising a thin-film substrate, composed of a flexible material, disposing a plurality of positioning holes for positioning and aligning the thin-film substrate to the curved substrate by a fitting aid, and a thin-film mask layer, formed on the thin-film substrate, having a visible pattern, wherein the thickness of the thin-film substrate is between 1 micrometer and 100 micrometers, the thickness of the thin-film mask layer is between 10 nanometers and 3000 nanometers; a hard sheet, having a curved surface matching with the curved substrate for pressing and pasting the thin-film mask to the photoresist layer of the curved substrate closely while the thin-film mask is attached to the curved substrate, and curves the surface of the thin-film mask; wherein the curved substrate fitting with the thin-film mask layer is exposed in the exposure assistant device to formed the curved surface pattern on the photoresist layer.

The present disclosure further provides a method for fitting a thin-film mask to a curved substrate, comprising the steps of: providing a curved substrate, a thin-film mask and a fitting aid, wherein the curved substrate having a photoresist layer; setting the thin-film mask between the curved substrate and the fitting aid; and pressing and fitting the thin-film mask to the curved substrate by using the fitting aid.

In order to make the structure and characteristics as well as the effectiveness of the present disclosure to be further understood and recognized, the detailed description of the present disclosure is provided as follows along with embodiments and accompanying figures.

### BRIEF DESCRIPTION OF THE DRAWINGS

FIG. 1A to 1D show a flow chart of steps for fitting a thin-film mask to a curved substrate according to various embodiments of the present disclosure;

FIGS. 2A and 2B show a top view and a cross-sectional view of the curved shell fabricated by the method of the present disclosure;

FIGS. 3A and 3B show a top view and a cross-sectional view of the thin-film mask applying on the positive resist according to an embodiment of the present disclosure;

FIGS. 4A and 4B show a top view and a cross-sectional view of the thin-film mask applying on the negative resist according to another embodiment of the present disclosure;

FIGS. 5A and 5B show a top view and a cross-sectional view of the fitting fixture according to an embodiment of the present disclosure;

FIG. 6A shows a top view of the fitting aid according to an embodiment of the present disclosure;

FIG. 6B to 6D show cross-sectional views along the A-A cut of the fitting aid according to various embodiments of the present disclosure;

FIG. 7A to 7E show a flow chart in cross-sectional view of fitting a thin-film mask to a curved substrate according to an embodiment of FIG. 1B of the present disclosure;

FIG. 8A to 8E show a flow chart in cross-sectional view of fitting a thin-film mask to a curved substrate according to another embodiment of FIG. 1B of the present disclosure;

FIG. 9A to 9E show a flow chart in cross-sectional view of fitting a thin-film mask to a curved substrate according to further another embodiment of FIG. 1B of the present disclosure;

FIG. 10A shows a top view of the fitting aid according to another embodiment of the present disclosure;

FIG. 10B shows a cross-sectional view along A-A cut of the FIG. 10A of the present disclosure; and

FIGS. 11 A to 11E show a flow chart in cross-sectional view of fitting a thin-film mask to a curved substrate according to an embodiment of FIG. 1D of the present disclosure

### DETAILED DESCRIPTION

According to the embodiments of the present disclosure, they provide a flexible material fitting aid and a hard material fitting aid to make the thin-film mask being curved and paste and fit the thin-film mask on a curved substrate closely. Therefore, the curved substrate with the thin-film mask could fabricate curved surface patterns on it by processing a lithography process.

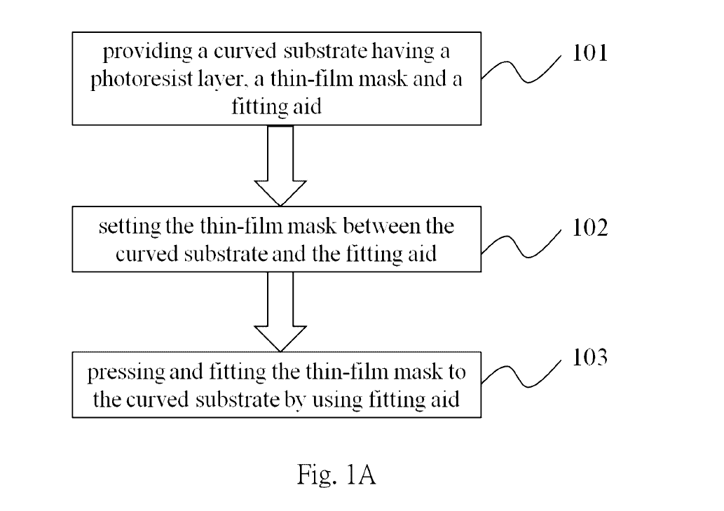

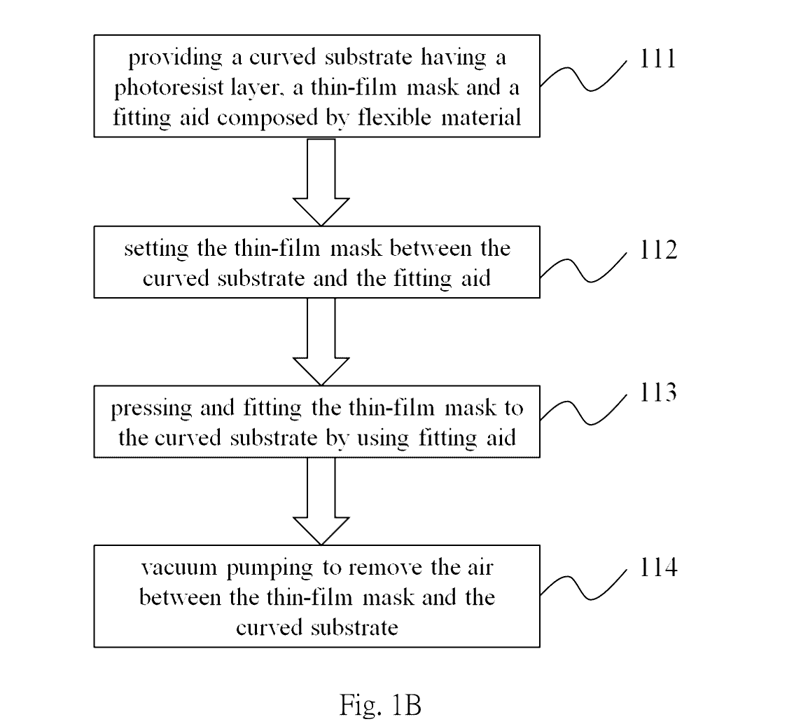

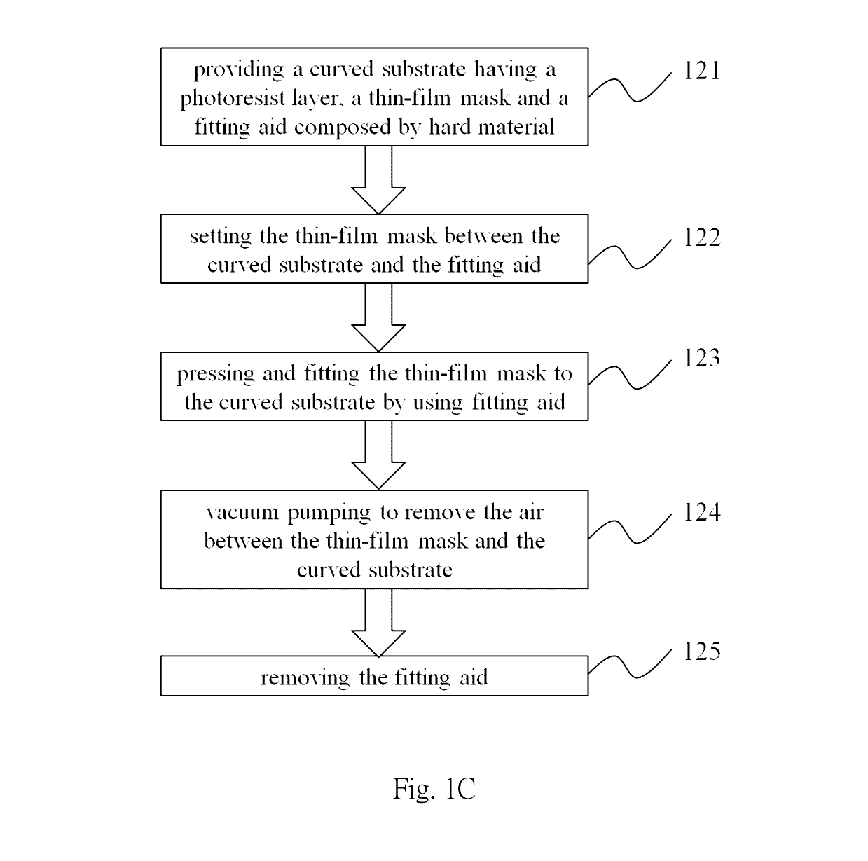

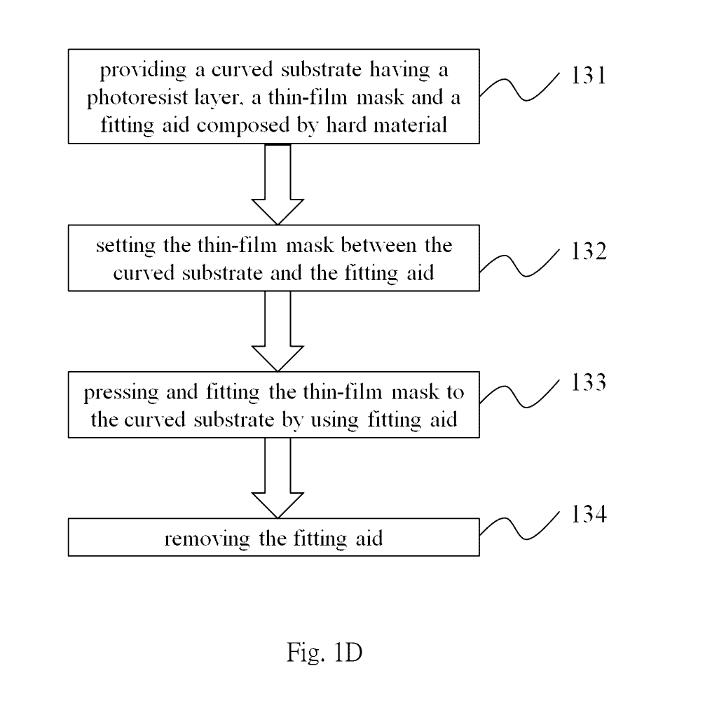

Next, please refer to FIG. 1A to 1D, the methods how a thin-film mask paste to a curved substrate according to various embodiments are disclosed.

First, as shown in FIG. 1A, it is a flow chart of steps for pasting a thin-film mask to a curved substrate according an embodiment of present disclosure, the steps comprising:

Step 101: providing a curved substrate having a photoresist layer, a thin-film mask and a fitting aid.

Step 102: setting the thin-film mask between the curved substrate and the fitting aid.

Step 103: pressing and fitting the thin-film mask to the curved substrate by using fitting aid.

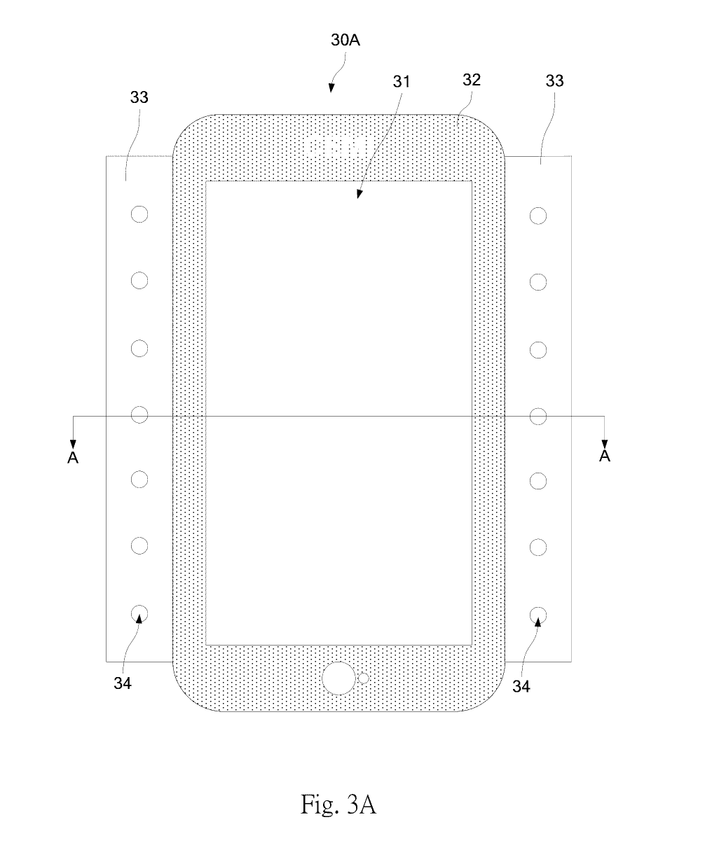

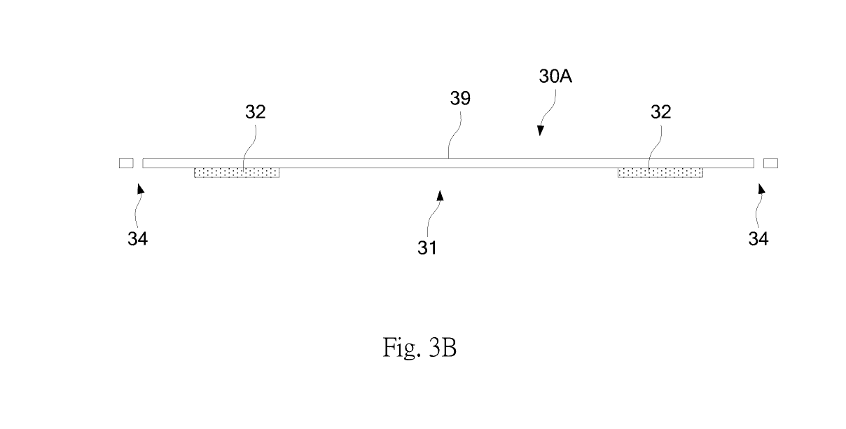

The relative content of embodiment of FIG. 1A would be illustrated with FIG. 3A to FIG. 7E later.

Please refer to FIG. 1B, which shows a flow chart of steps for pasting a thin-film mask to a curved substrate according another embodiment of present disclosure, the steps comprising:

Step 111: providing a curved substrate having a photoresist layer, a thin-film mask and a fitting aid composed by flexible material.

Step 112: setting the thin-film mask between the curved substrate and the fitting aid.

Step 113: pressing and fitting the thin-film mask to the curved substrate by using fitting aid.

Step 114: vacuum pumping to remove the air between the thin-film mask and the curved substrate.

In the embodiment of FIG. 1B, it provides a fitting aid composed of flexible materials, such as the silica gel with lamination bonding or other flexible materials with porous property, to help the thin-film mask fit on the curved substrate having photoresist layer. Besides, in the embodiment of FIG. 1B, it also provides a vacuum pumping step to remove the air between the thin-film mask and the curved substrate to make the thin-film mask and the curved substrate fitting closely. Base on the characteristics mentioned above, the fitting aid could paste on the thin-film mask closely and forming a three-layer structure is composed of the fitting aid, the thin-film mask and the curved substrate to process a lithography process. Also, if the refractive index of the material of fitting aid is greater than the air, the effect of the exposure will be better because of the collimation of the light incident to the curved substrate is raised during the lithography process.

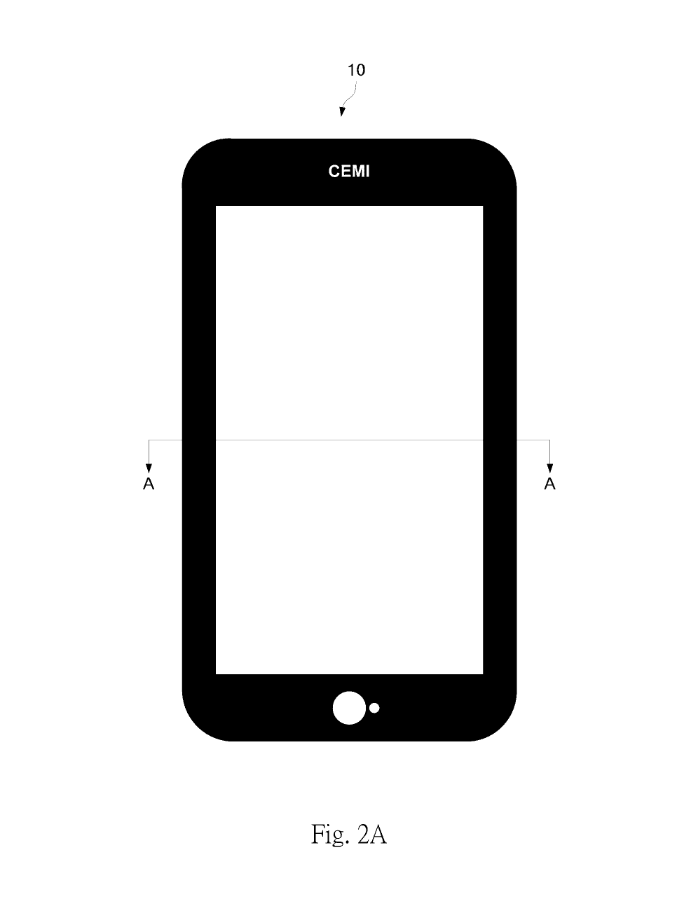

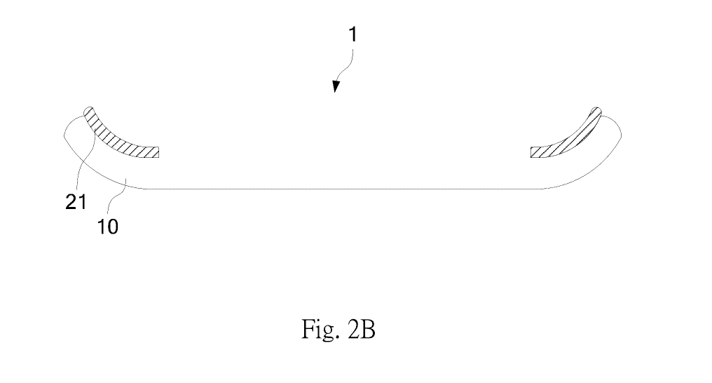

Refer to FIGS. 2A and 2B, which are a top view and a cross-sectional view of the curved shell 1 which fabricated by the skill of the present disclosure, wherein FIG. 2B is a cross-sectional view along the A-A cut of the FIG. 2A. According to the figures, the curved substrate 10 has a photoresist layer 20 on which a curved surface pattern has been prepared. However, the preparation of the curved surface pattern is quite difficult. The lack of the precision of traditional screen printing results in a poor resolution of the curved surface pattern and fails to meet the high resolution need of consumer electronics. Comparatively speaking, the present disclosure provides a thin-film mask fitting perfectly on the photoresist layer of the curved substrate 10 formed by a high precision curved thin-film mask. After that, processing a lithography process on the curved substrate having the thin-film mask to get the high resolution curved surface patterns of the FIG. 2A.

Next, referring to FIG. 3A to FIG. 7E of the present disclosure to illustrate the fitting apparatus and methods of the present disclosure, especially the thin-film mask, the fitting aid and the fitting fixture used to paste the thin-film mask precisely and closely.

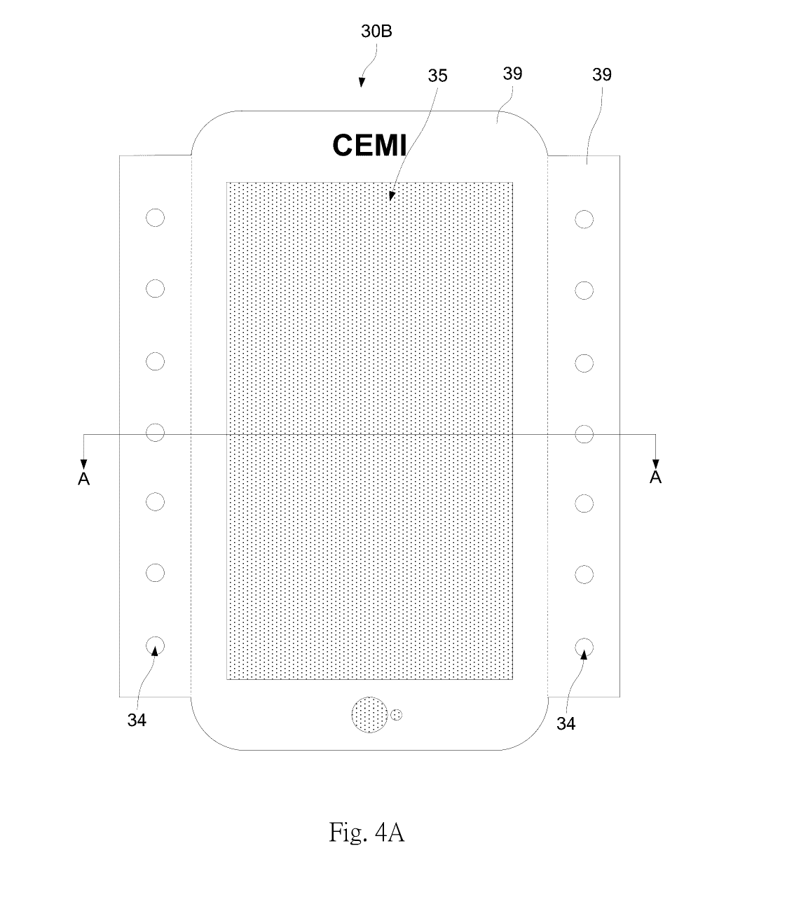

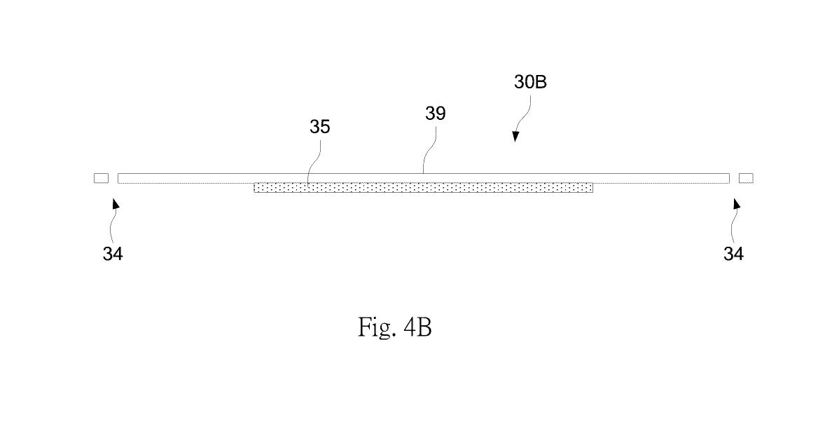

Refer to FIG. 3A and FIG. 3B of the present disclosure, wherein FIG. 3B is a cross-sectional view along the A-A cut of FIG. 3A, which show a thin-film mask example used for the positive resists. In the other side, FIG. 4A and FIG. 4B show an example that the thin-film mask is used for the positive resists, wherein FIG. 4B is a cross-sectional view along the A-A cut of FIG. 4A. As the figures tell, the thin-film masks cover areas of two embodiments are in direction opposition.

The thin-film mask 30A of FIG. 3A and FIG. 3B comprising a thin-film substrate 39 and a thin-film mask layer 32 formed thereon. The thin-film mask 30A of FIG. 4A and FIG. 4B comprising a thin-film substrate 39 and a thin-film mask layer 35 formed thereon. Said thin-film substrate 39 is composed of a flexible material, such as PET. And the thin-film mask layer 32, 35 formed on the thin-film substrate 39, having a visible pattern and used to attach to the photoresist layer of the curved substrate, wherein the thickness of the thin-film substrate 39 is between 1 micrometer and 100 micrometers, the thickness of the thin-film mask layer is between 10 nanometers and 3000 nanometers. The thin-film mask layer 32, 35 is composed of the metal materials and has high flexibility when the thickness is ranged from 10 micrometers to 3000 micrometers, thus it is suitable for applying on the curved surface. In addition, the thin-film substrate 39 comprising a plurality of positioning holes for positioning and aligning the thin-film substrate to the curved substrate.

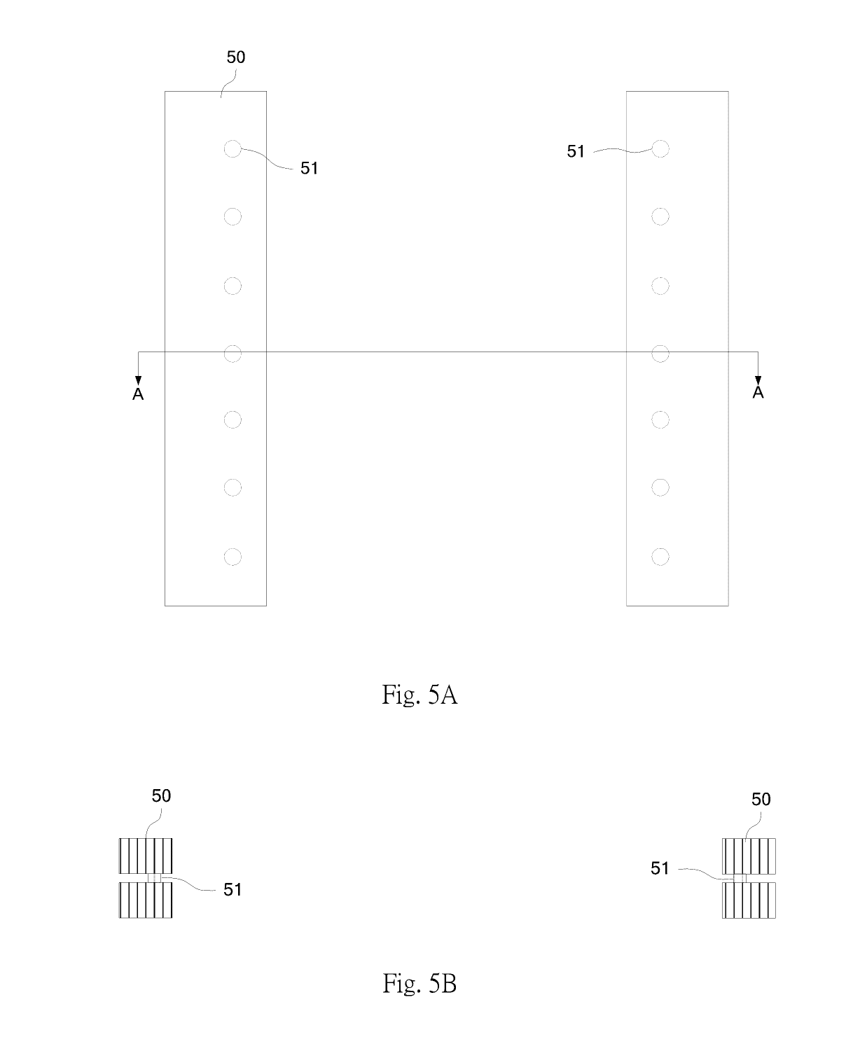

Next, please refer to FIG. 5A and FIG. 5B, which shows top view and a cross-sectional view of a fitting fixture according to an embodiment of the present disclosure. As shown in the figure, the fitting fixture 50 having a plurality of position latch 51 corresponding to the position holes 34 of the thin-film mask 30A, 30B. Therefore, the fitting fixture 50 can hold the thin-film mask 30A, 30B truly and help them position precisely.

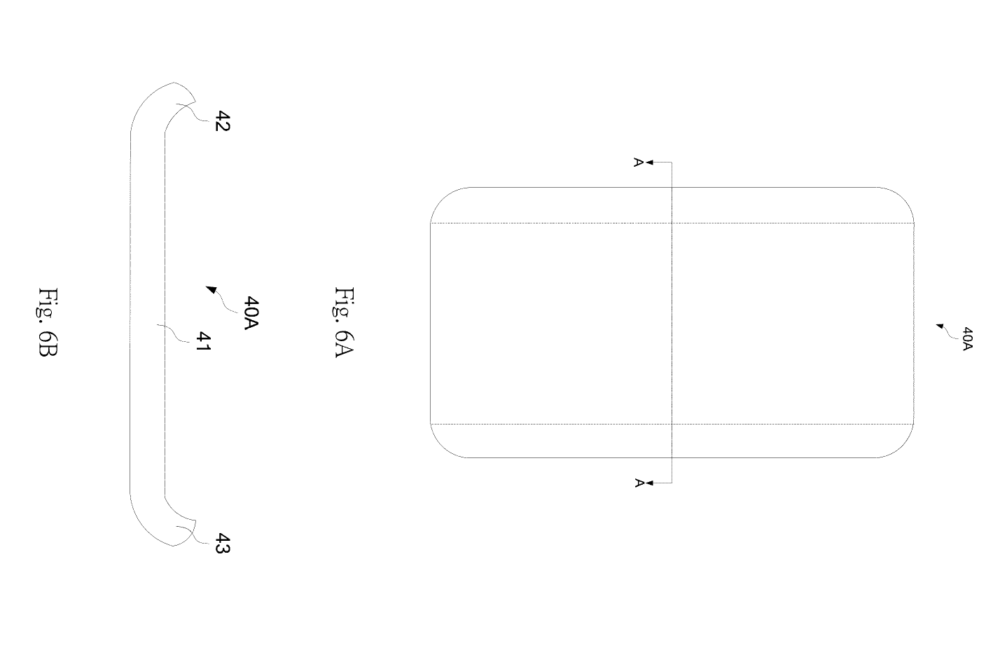

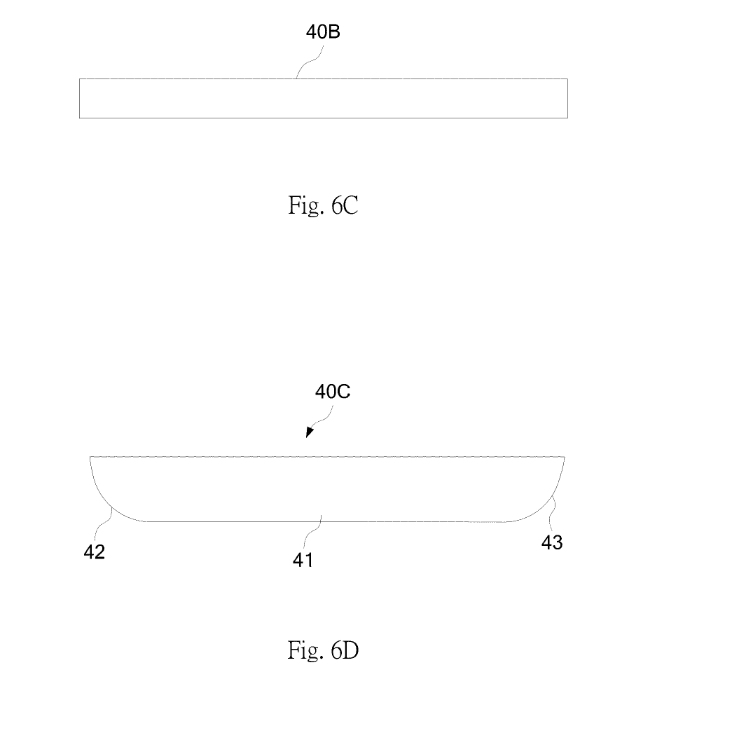

Please refer to FIG. 6A, which shows a top view of the fitting aid according to an embodiment, and FIG. 6B to FIG. 6D are the cross-sectional views along the A-A cut of various type of fitting aid of the present disclosure. As shown in FIG. 6B, the shape of fitting aid comprising a forming bottom 41, a first curved side 42 and a second curved side 43 is prepared previously to fit the curved substrate 10 for enhancing the processing speed. In other preferred embodiments, as shown in FIGS. 6C and 6D, the fitting aid could be a planar structure (40B) or a designed structure having a curved bottom matching with the curved substrate 10 (40C). The fitting aid is composed of single material, however, it could also be formed in different shapes by other different materials, such as silicone, silicone oil coated soft outer layer material, silicon organic material, fluorine-containing organic material or the mixture thereof. Base on the properties of those materials, the fitting aid could be a well deformation to help the thin-film mask fit on the curved surface 10.

It can be seen from the embodiments mentioned above that the efficiency will increase if the fitting aid is composed of an elastic material with high transmittance, such as could be passed through by the light having a wavelength between 300 nanometers and 500 nanometers. The collimation of the following exposure process increases as the material properties of the high transmittance elastic material, jointly, the printing resolution of the exposure process increases as well.

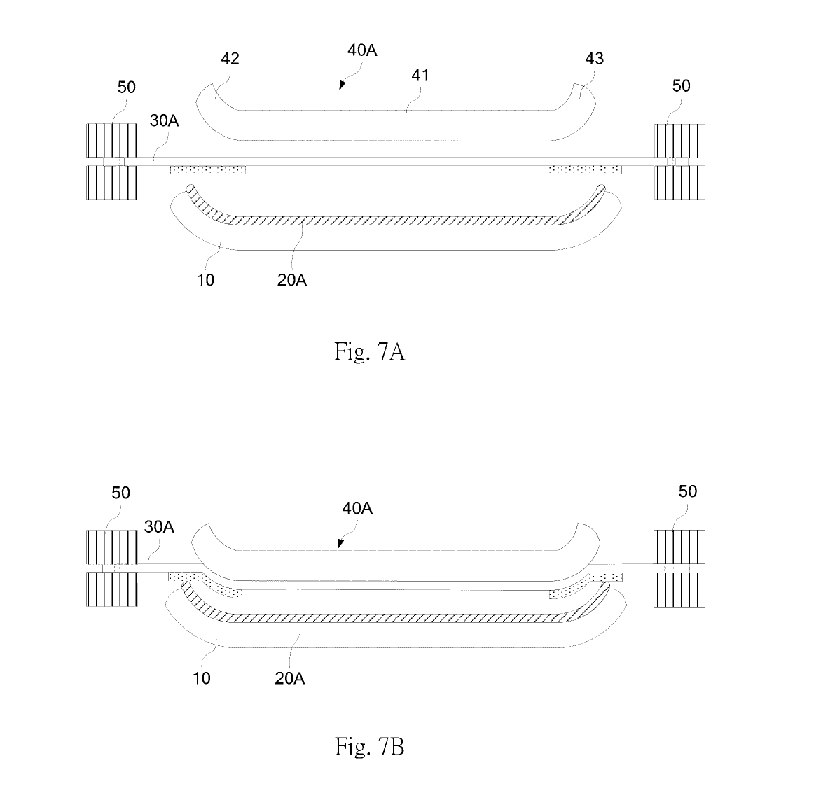

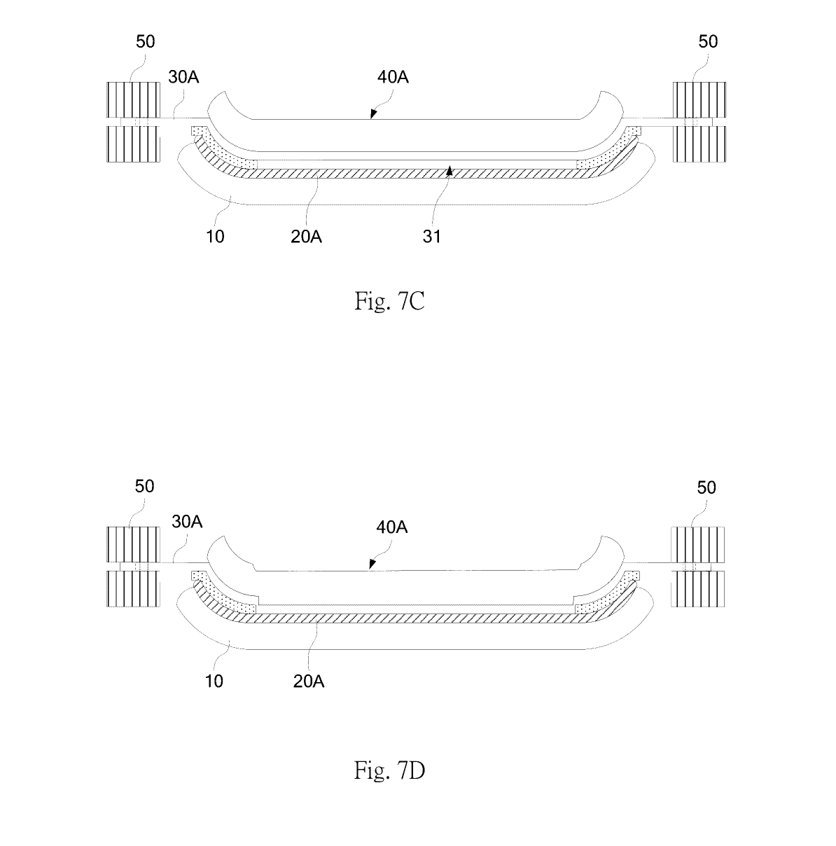

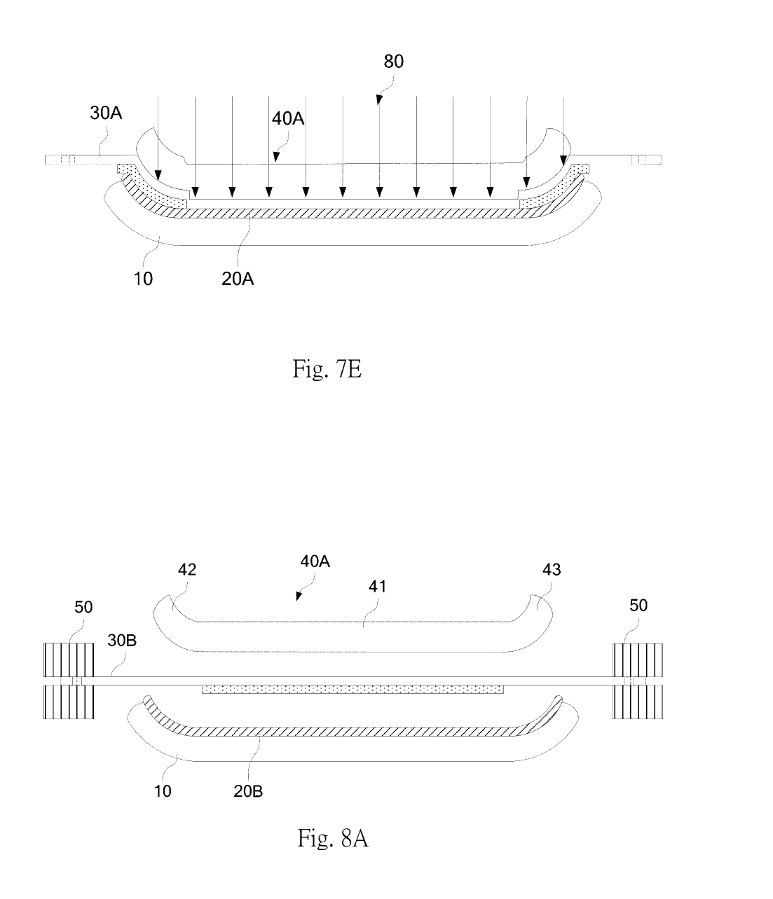

Next, please refer to FIG. 7A to FIG. 7E, which show a flow chart in cross-sectional view of fitting a thin-film mask to a curved substrate according to an embodiment of FIG. 1B of the present disclosure. In the embodiment, the fitting aid 40A and the thin-film mask 30A for positive resists layer 20A are used.

First, as shown in FIG. 7A, the fitting fixture 50 hold the thin-film mask 30A to position precisely to the curved surface 10 with positive photoresist layer 20A, and the fitting aid 40A is prepared to press and to fit after that. The figure illustrates the step 111 and step 112 of FIG. 1B which says providing a curved substrate having a photoresist layer, a thin-film mask and a fitting aid, wherein the fitting aid is composed by flexible material, and setting the thin-film mask between the curved substrate and the fitting aid.

Next, as shown in FIGS. 7B and 7C, the thin-film mask 30A becomes deformed and fits to the curved surface 10 while the fitting aid 40A keeps pressing on them. At this time, the positive photoresist layer 20A of the curved substrate 10 and the thin-film mask layer 32 of the thin-film mask 30A are fitting together, and supported by the air of the hollow area 31 which formed between the thin-film mask 30A and the positive photoresist layer 20A, which exactly express the meaning of step 113 FIG. 1B that pressing and fitting the thin-film mask to the thin-film mask on the curved substrate by using fitting aid.

Next, as mentioned in step 114 of FIG. 1B, it processes a vacuum pumping method to remove the air between the thin-film mask and the curved substrate. Refer to FIG. 7D, the air of the hollow area 31 between the thin-film mask 30A and the positive photoresist layer 20A in FIG. 7C would be removed, which results in the fitting aid 40A with flexible material deformed again to fill the space. Therefore, the fitting aid 40A, the thin-film mask 30A and the positive photoresist layer 20A would tightly fit to each other temporarily. It would bring the advantages for the following lithography process.

At last, removing the fitting fixture 50 as shown in FIG. 7E, then the exposure device could process the lithography by applying the ultraviolet light.

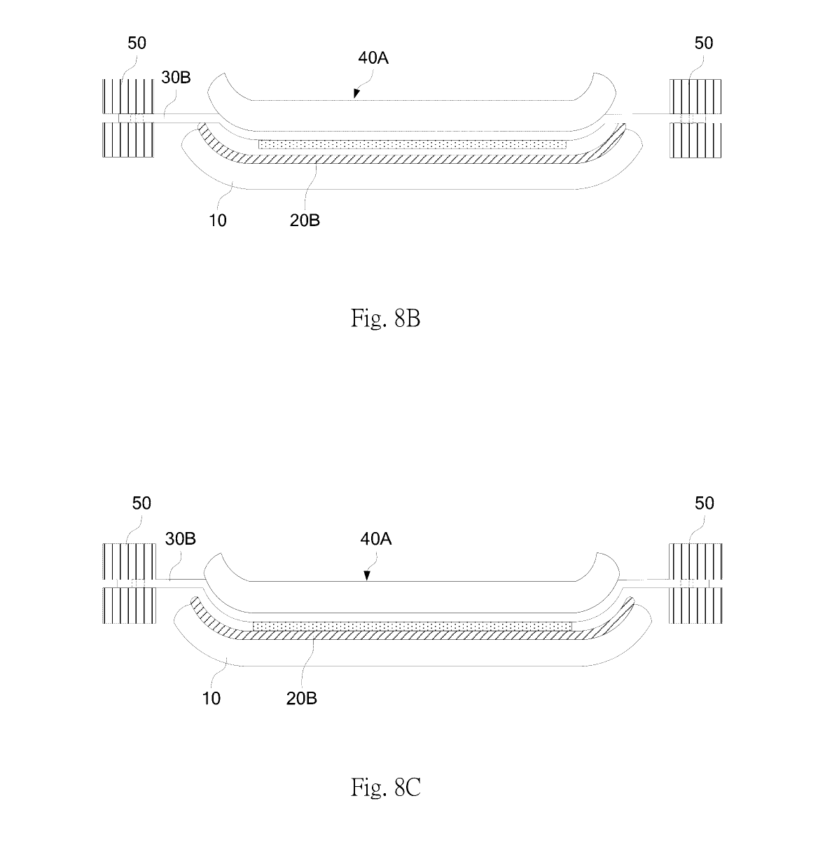

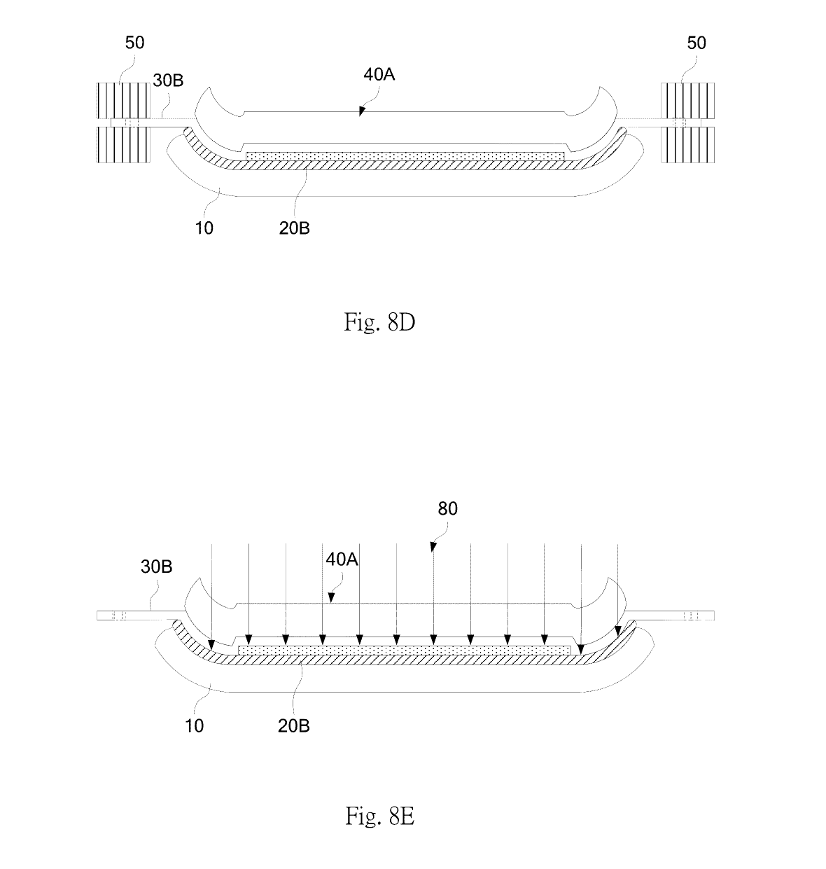

All everything else equal, FIG. 8A to FIG. 8E show a embodiment using a negative photoresist layer 20B and a corresponding thin-film mask 30B thereof to forming a curved surface pattern. The process and the remarkable fact of negative resist embodiment is similar to the positive resist one shown on FIG. 7A to FIG. 7E, thus, no more tautology here. The different between those two embodiments is the positions where the thin-film mask 30A, 30B having a deformation is different which results from the thin-film mask layer 35 and the thin-film mask layer 32 are locating on the different position. However, though the deformation part is different, the thin-film mask 30B could still having a corresponding deformation suitable for negative resist use after the pressing pressure of the flexible fitting aid 40A and the air removing by vacuum pumping step.

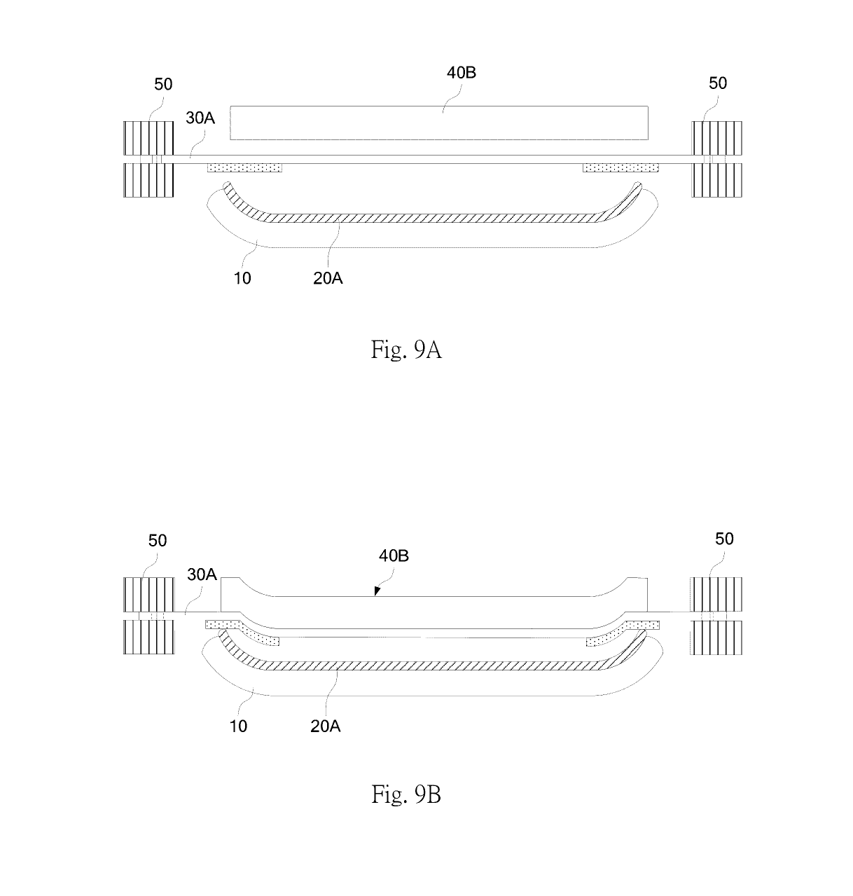

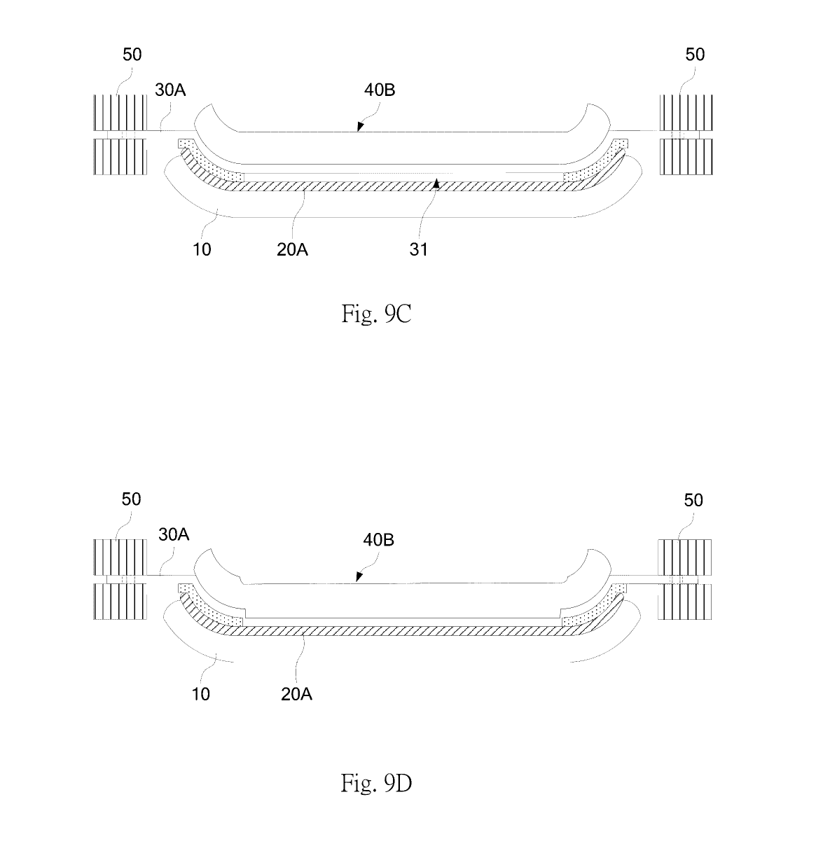

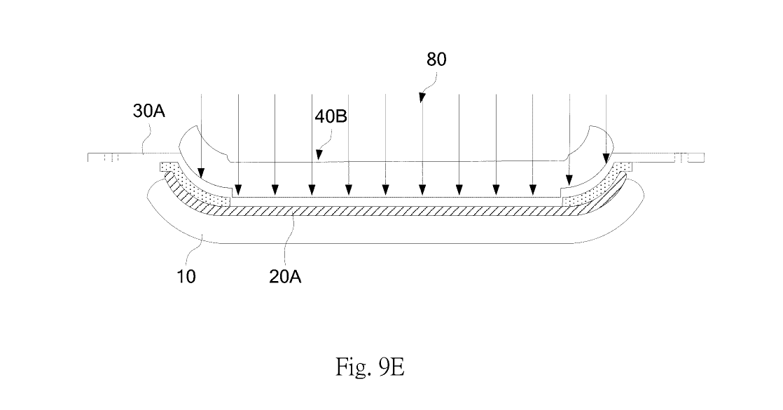

Next, please refer to FIG. 9A to FIG. 9E, they illustrate a different embodiment which applying other kind of the fitting aid 40B to help the thin-film mask 30A paste on the curved surface closely. In the embodiment, the fitting aid 40B is a simply planar structure and the exterior of the fitting aid is not adjusted before use. However, it does not affect the effect of the fitting aid. Base on the characteristics of the flexible material of the fitting aid 40B, a planar structure fitting aid 40B could still have a corresponding deformation by an outer force to help the thin-film mask 30A pasting closely to the curved substrate 10 while the thin-film mask is attached to the curved substrate.

Besides, the fitting aid of present disclosure could also be formed as the type which the outside of the fitting aid is solid silicone gel and the liquid solid gel is contained inside of the fitting aid. This type of the fitting aid provides the same feature that it would have a corresponding deformation during the pressing and fitting process. Further, the material of fitting aid also extends the reach of other non-silicone flexible materials, such as an elastic material with high transmittance.

The embodiments mentioned above fully illustrate all the aspect of the fitting aid composed of the flexible materials. Next, please refer to the figures and the following description, the characteristics of the fitting aid composed of hard materials is disclosed.

Please refer to FIG. 1C, which shows a flow chart of steps for pasting a thin-film mask to a curved substrate according another embodiment of present disclosure, where in the fitting aid is composed by hard material, the steps comprising:

Step 121: providing a curved substrate having a photoresist layer, a thin-film mask and a fitting aid composed by hard material.

Step 122: setting the thin-film mask between the curved substrate and the fitting aid.

Step 123: pressing and fitting the thin-film mask to the curved substrate by using fitting aid.

Step 124: vacuum pumping to remove the air between the thin-film mask and the curved substrate.

Step 125: removing the fitting aid.

Please refer to FIG. 1D, which shows a flow chart of steps for pasting a thin-film mask to a curved substrate according further another embodiment of present disclosure, where in the fitting aid is composed by hard material, the steps comprising:

Step 131: providing a curved substrate having a photoresist layer, a thin-film mask and a fitting aid composed by hard material.

Step 132: setting the thin-film mask between the curved substrate and the fitting aid.

Step 133: pressing and fitting the thin-film mask to the curved substrate by using fitting aid.

Step 134: removing the fitting aid.

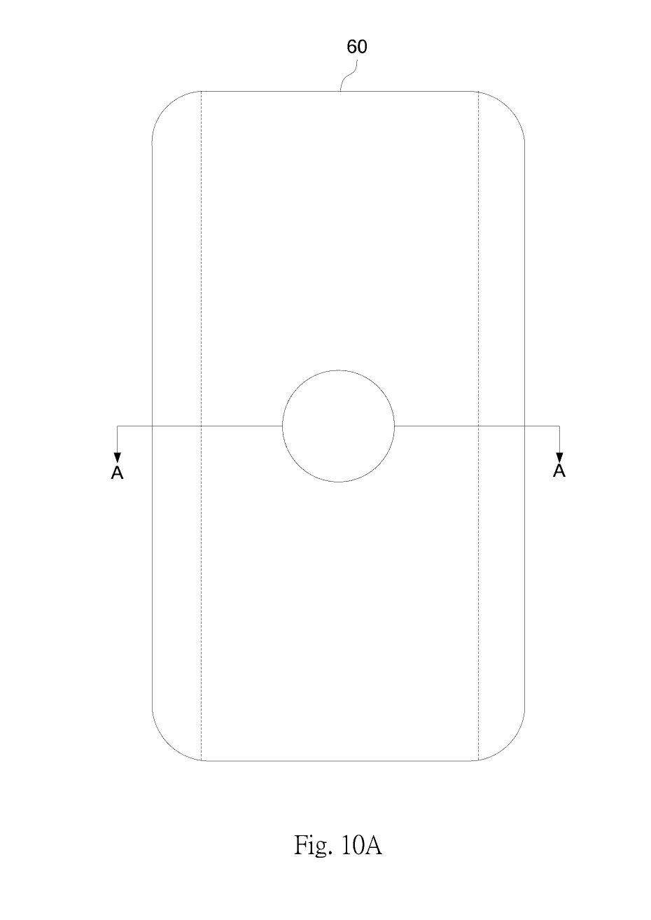

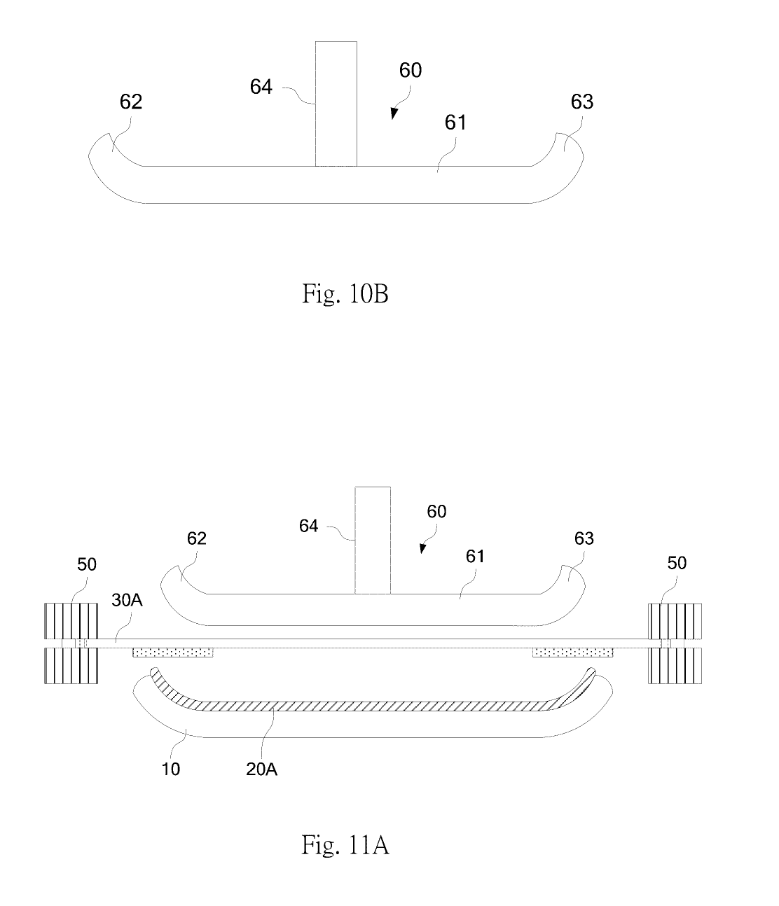

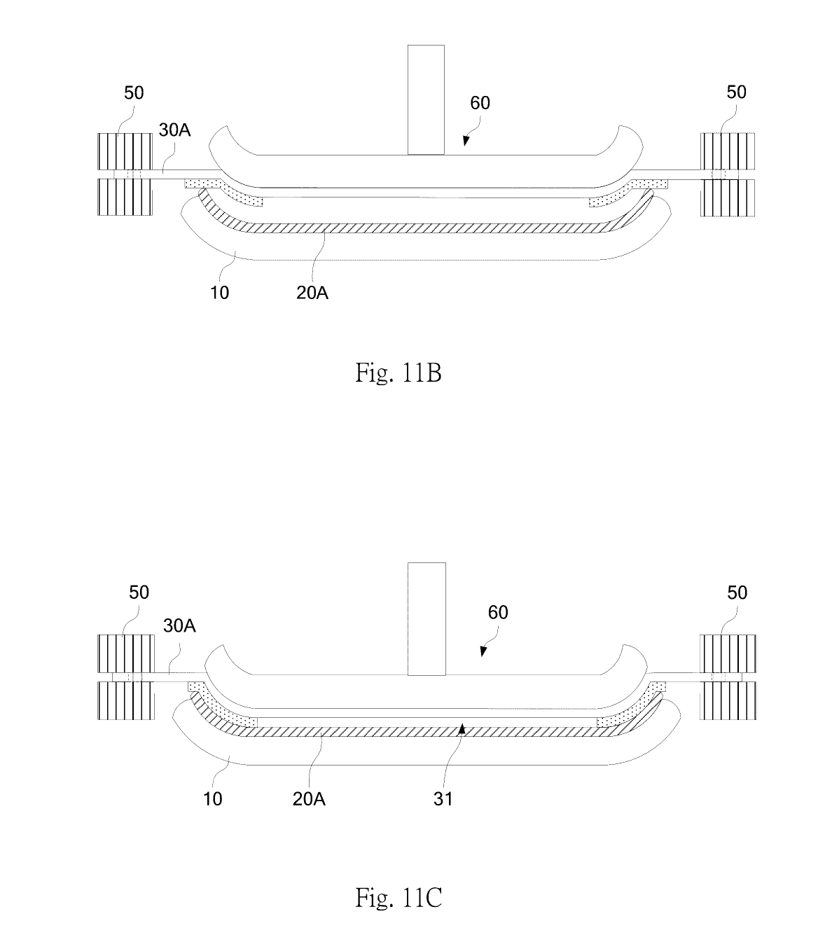

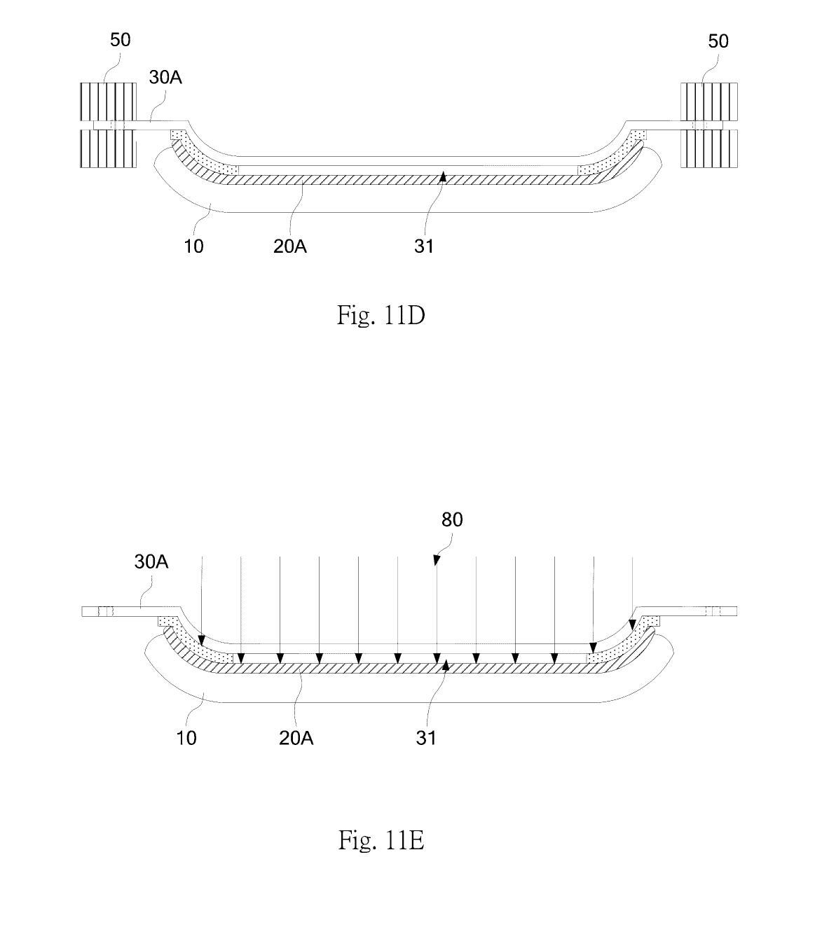

Next, refer to FIG. 10A, FIG. 10B and FIG. 11A to 11E, the shape of fitting aid 60 composed of a hard material is prepared previously and fit on the curved substrate 10, as FIG. 10B shows, fitting aid 60 comprising a bottom 61, a first curved site 62, a second curved site 63 and a supporting rib 64. The supporting rib 64 is used to help position the fitting aid 60 because of the less flexibility of hard material. Also, on the bottom of the fitting aid 60 where contact to the thin-film mask can set up a flexible thin-film to enhance the effect of fitting and pasting.

Refer to FIG. 11A to FIG. 11E, the process is the same as the process of FIG. 1C and FIG. 1D. FIG. 11A shows that providing a curved substrate having a photoresist layer, a thin-film mask and a fitting aid composed of hard material, and setting the thin-film mask between the curved substrate and the fitting aid which is described in steps 121 to 122 and steps 131 to 132.

FIG. 11B to FIG. 11C show the step of pressing and fitting the thin-film mask to the curved substrate by using fitting aid which described in step 123 and step 133.

FIG. 11D shows the step of removing the fitting aid which described in step 125 and step 134. Though the step 124 does not show in the figures, however, it would be obviously the thin-film substrate 39 will deform and fit on the positive photoresist layer 20A on the curved substrate 10 if the vacuum pumping is executed.

To sum up, by the methods and the apparatus of present disclosure, the tools could easily to match each other, and the curved surface patterns on the curved substrate can be mass production by the light resist technique, and increase the quality, the product precision and the yield of products.

Accordingly, the present disclosure conforms to the legal requirements owing to its novelty, non-obviousness, and utility. However, the foregoing description is only embodiments of the present disclosure, not used to limit the scope and range of the present disclosure. Those equivalent changes or modifications made according to the shape, structure, feature, or spirit described in the claims of the present disclosure are included in the appended claims of the present disclosure.

1. A thin-film mask for attaching to a curved substrate to form a photoresist layer on the curved substrate, comprising:
a thin-film substrate, composed of a flexible material; and
a thin-film mask layer, formed on the thin-film substrate, having a visible pattern and used to attach to the photoresistlayer of the curved substrate;
wherein a thickness of the thin-film substrate is between 1 micrometer and 100 micrometers, the thickness of the thin-film mask layer is between 10 nanometers and 3000 nanometers.

2. The thin-film mask of claim 1, wherein the flexible material is selected from PET.

3. The thin-film mask of claim 1, further comprising a plurality of positioning holes, formed on the thin-film substrate, positioning and aligning the thin-film substrate to the curved substrate by a fitting aid.

4. A fitting aid for the thin-film mask of claim 1, which assists the thin-film mask to paste on the curved substrate when applying a pressure and acts as an interface between the thin-film mask and a exposure assistant device, comprising:
a flexible sheet, composed of an elastic material with high transmittance, passed through by a light having a wavelength between 300 nanometers and 500 nanometers, deformed by an outer force to make the thin-film mask pasting closely on the photoresist layer of the curved substrate while the thin-film mask is attached to the curved substrate, and curved the thin-film mask.

5. The fitting aid of claim 4, wherein the elastic material with high transmittance is selected from silicone, silicone oil coated soft outer layer, silicon organic material and fluorine-containing organic material.

6. The fitting aid of claim 4, wherein a bottom of the flexible sheet is designed to have a surface matching the curved substrate.

7. A fitting and exposure assistant device for forming a photoresist layer with a curved surface pattern on a curved substrate, comprising:
a thin-film mask comprising:
a thin-film substrate, composed of a flexible material; and
a thin-film mask layer, formed on the thin-film substrate, having a visible pattern;
wherein a thickness of the thin-film substrate is between 1 micrometer and 100 micrometers, the thickness of the thin-film mask layer is between 10 nanometers and 3000 nanometers;
a flexible sheet, composed of a elastic material with high transmittance, passed through by the light having a wavelength between 300 nanometers and 500 nanometers, wherein the flexible sheet is deformed by an outer force to make the thin-film mask pasting on the photoresist layer of the curved substrate closely while the thin-film mask is attached to the curved substrate, and curves the surface of the thin-film mask;
wherein the flexible sheet, the thin-film mask layer and the curved substrate are piled up in order, and exposed together in a exposure device to formed the curved pattern on the photoresist layer.

8. The fitting and exposure assistant device of claim 7, wherein the thin-film mask further comprises a plurality of positioning holes, formed on the thin-film substrate, for positioning and aligning the thin-film substrate to the curved substrate by a fitting aid.

9. The fitting and exposure assistant device of claim 7, wherein the elastic material with high transmittance is selected from silicone, silicone oil coated soft outer layer, silicon organic material and fluorine-containing organic material.

10. The fitting and exposure assistant device of claim 7, wherein a bottom of the flexible sheet is designed to have a surface matching the curved substrate.

11. A fitting and exposure assistant device for forming a photoresist layer with a curved surface pattern on a curved substrate, comprising:
a thin-film mask comprising:
a thin-film substrate, composed of a flexible material, disposing a plurality of positioning holes for positioning and aligning the thin-film substrate to the curved substrate by a fitting aid; and
a thin-film mask layer, faulted on the thin-film substrate, having a visible pattern;
wherein a thickness of the thin-film substrate is between 1 micrometer and 100 micrometers, the thickness of the thin-film mask layer is between 10 nanometers and 3000 nanometers;
a hard sheet, having a curved surface matching with the curved substrate, for pressing and pasting the thin-film mask to the photoresist layer of the curved substrate closely while the thin-film mask is attached to the curved substrate, and curves the surface of the thin-film mask;
wherein the curved substrate fitting with the thin-film mask layer is exposed in the exposure assistant device to formed the curved surface pattern on the photoresist layer.

12. The fitting and exposure assistant device of claim 11, wherein the flexible material is selected from PET.

13. The fitting and exposure assistant device of claim 11, wherein the thin-film mask pressing and pasting to the photoresist layer of the curved substrate closely by a vacuum pumping force.

14. A method for fitting a thin-film mask to a curved substrate, comprising the steps of:
providing a curved substrate, a thin-film mask and a fitting aid, wherein the curved substrate having a photoresist layer;
setting the thin-film mask between the curved substrate and the fitting aid; and
pressing and -fitting the thin-film mask to the curved substrate by using the fitting aid.

15. The method as claimed in claim 14, further comprising a step of vacuum pumping to remove the air between the thin-film mask and the curved substrate after the step of pressing and fitting step.

16. The method as claimed in claim 14, wherein the fitting aid is composed of a flexible material.

17. The method as claimed in claim 16, wherein the flexible material is composed of an elastic material with high transmittance, which is passed through by the light having a wavelength between 300 nanometers and 500 nanometers.

18. The method as claimed in claim 17, wherein the elastic material with high transmittance is selected from silicone, silicone oil coated soft outer layer, silicon organic material and fluorine-containing organic material.

19. The method as claimed in claim 15, wherein the fitting aid is composed of a flexible material.

20. The method as claimed in claim 19, wherein the flexible material is composed of an elastic material with high transmittance, which is passed through by a light having a wavelength between 300 nanometers and 500 nanometers.
